(19) United States
(12) Patent Application Publication
(10) Pub. No.: US 2013/0285677 A1
(43) Pub. Date: Oct. 31, 2013

(54) WATER CONTENT MEASURING APPARATUS

(71) Applicant: Hammertech AS, Bergen (NO)

(72) Inventor: Erling Hammer, Frekhaug (NO)

(73) Assignee: Hammertech AS

(21) Appl. No.: 13/878,821

(22) PCT Filed: Oct. 12, 2011
(86) PCT No.: PCT/NO11/00291

§ 371 Date: Jul. 9, 2013

(30) Foreign Application Priority Data
Oct. 12, 2010 (NO) 20101411

(51) Int. Cl. G01R 27/26

(52) U.S. Cl. CPC G01R 27/2611
USPC 324/655

(57) ABSTRACT

A water content measuring apparatus, for measuring water content present in a fluid flow through a tube, includes a pulse generator for generating in operation a temporal series of excitation pulses, a coil arrangement disposed around the tube adapted to be excited into resonance by the series of excitation pulses and interact with the fluid flow through the tube, and a signal processor adapted to receive resonance signals from the coil arrangement for determining a water content present within the tube. The coil arrangement includes a resonance coil having a length-to-diameter ratio which is at least 3:1, and wherein the resonance coil includes at least 10 turns.

### FIELD OF THE INVENTION

The present invention relates to water content measuring apparatus, for example to a water content measuring apparatus for monitoring water content in fluid flows, for example for monitoring water content in fluid flows wherein conditions for hydrate deposit formation can potentially arise. Moreover, the present invention relates to methods of measuring water content in fluid flows, for example to methods of measuring water content in fluid flows in conditions wherein hydrate deposit formation can potentially arise. Furthermore, the present invention concerns software products recorded on machine-readable media, wherein the software products are executable on computing hardware for implementing aforesaid methods.

### BACKGROUND OF THE INVENTION

It is known to employ a pair of coils of wire exhibiting mutually different responses and excited with alternating signals for determining phase characteristics of a fluid region intersected by magnetic and electrical fields generated by the pairs of coils when excited. Such coils conventionally have relatively few turns, for example less than 10 turns each, and can determine fluid composition to within an accuracy of a few percent by way of measurement of their resonance characteristics, for example resonance Q-factor. The pair of coils is susceptible, for example, to being used to monitor fluids extracted from a production borehole when water, oil, sand particles and scum can potentially simultaneously be present in the fluids. Apparatus for determining phase characteristics of a fluid region are described in a published international PCT application no. WO2004/025288A1, “Method and arrangement for measuring conductive component current of a multiphase fluid flow and uses thereof”, inventor Erling Hammer.

A contemporary issue is that geological oil reserves are becoming rapidly depleted, requiring oil companies to revert to difficult and expensive off-shore drilling and production to meet World demand for oil; the World demand is presently estimated to be 85 million barrels of oil equivalent per day. Many newly discovered oil and gas fields, for example in the Barrent Sea lying North of Norway, are found to contain a higher ratio of gas to oil than expected from earlier discovered oil and gas fields. Consequently, there is found to be a need to monitor to an increasing extent gas production in Northern latitudes which are often subjected to severe operating conditions, for example low ambient operating temperatures, for example below 0° C.

A contemporary problem encountered with gas production is spontaneous formation of hydrate deposits which can block tubes completely and therefore threaten gas production with associated financial loss. Hydrate formation occurs when gas hydrocarbon molecules, for example on account of strong polarization of their hydrogen atoms, attract oxygen atoms of water molecules so that the hydrocarbon molecules become encapsulated in water molecules to form miniature hydrate ice crystals which can precipitate to cause aforementioned hydrate deposit blockages in tubes. The blockages grow initially on inside walls of tubes, and eventually obstruct a central region of the tubes. Once hydrate ice crystal deposition commences on the inside walls, hydrate crystal nucleation is enhanced such that hydrate blockages can potentially form rapidly, for example within minutes. Moreover, the blockages are also often rather difficult to remove when formed, sometimes requiring costly “pigging” or heat treatment to be performed. A conventional approach to hinder hydrate formation is to include additives in a flow of gas. However, using additives is expensive and can also potentially cause a degree of contamination in gas flows.

Contemporary sensors and associated measuring instruments for sensing hydrate formation in tubes are complex and costly, thereby limiting locations whereat they can be installed in gas production systems. Consequently, many locations along gas tubes and pipes which could beneficially be provided with measuring instruments capable of detecting potential formation of hydrate deposits are hindered from being accordingly equipped on account of cost of conventional hydrate measuring instruments.

### SUMMARY OF THE INVENTION

The present invention seeks to provide a more cost effective and robust water content measuring apparatus, for example for detecting conditions under which hydrate deposits are potentially susceptible to arise.

According to a first aspect of the present invention, there is provided a water content measuring apparatus as claimed in appended claim 1: there is provided a water content measuring apparatus for measuring water content present in a fluid flow through a tube, characterized in that the apparatus includes a generator for generating in operation an excitation signal, a coil arrangement disposed around the tube adapted to be excited into resonance by the excitation signal and interact with the fluid flow through the tube, and a signal processor adapted to receive resonance signals from the coil arrangement for determining a water content present within the tube, wherein the coil arrangement includes a resonance coil having a length-to-diameter ratio which is at least 3:1, and wherein the resonance coil includes at least 10 turns.

The invention is of advantage in that the apparatus is capable of measuring minute quantities of water present within the tube, for example indicative of potential early hydrate formation.

Optionally, the generator is operable to generate the excitation signal to include a temporal series of excitation pulses.

Optionally, the resonance coil employs at least 15 turns, more beneficially at least 20 turns, yet more beneficially at least 25 turns.

Optionally, the water content measuring apparatus is implemented so that the tube and its associated coil arrangement are surrounded by an electrostatic shield for screening the coil arrangement when in operation.

Optionally, the water content measuring apparatus further includes a sensor arrangement for sensing low-frequency electrical conductivity and temperature on an inside wall of the tube and for providing corresponding sensor signals to the signal processor for enabling the signal processor to compute the water content within the tube independently of the salinity of the water content.

Optionally, the water content measuring apparatus is implemented so that the coil arrangement includes excitation, resonance and pickup coils, wherein the excitation coil is coupled to the generator, the pickup coil is coupled to the signal processor, and the resonance coil is coupled to a tuning capacitor (C) for providing a resonance characteristic which is sensitive to water content within the tube. More optionally, the coils are fabricated from at least one of: individually insulated Litz wires, insulated metallic tape. More optionally, the coils are silver plated on their peripheral external surfaces to reduce their surface electrical resistance.

Optionally, the water content measuring apparatus is implemented so that at least one of the generator and the signal processor are adapted to be spatially remote from the tube and its coil arrangement in operation.

Optionally, the water content measuring apparatus is adapted to monitor conditions in which potential hydrate formation within the tube can arise.

Optionally, the water content measuring apparatus is implemented so that the tube is fabricated from at least one of: polycarbonate polymer, acrylic polymer, PEEK polymer. PEEK polymers are obtained by step-growth polymerization by dialkylation of bisphenolate salts. Typically, PEEK is produced by way of a reaction of 4,4′-difluorobenzophenone with a diSodium salt of hydroquinone, which is generated in situ by deprotonation with Sodium Carbonate. PEEK manufacture employs a reaction which is conducted at a temperature of around 300° C. in polar aprotic solvents, for example such as diphenylsulphone. PEEK is a semicrystalline thermoplastic with excellent mechanical and chemical resistance properties that are retained to high temperatures. PEEK exhibits a Young's modulus of 3.6 GPa, and its tensile strength is in a range of 90 to 100 MPa. Moreover, PEEK has a glass transition temperatures at around a temperature of 143° C. and melts at a temperature around 343° C. Furthermore, PEEK is highly resistant to thermal degradation as well as attack by both organic and aqueous environments. However, PEEK is attacked by halogens and strong Bronsted and Lewis acids as well as some halogenated compounds and aromatic hydrocarbons at high temperatures.

According to a second aspect of the invention, there is provided a method of measuring water content present in a fluid flow through a tube, characterized in that the method includes:
(a) using a generator to generate in operation an excitation signal for exciting a coil arrangement disposed around the tube for interacting with the fluid flow through the tube; and
(b) receiving at a signal processor resonance signals from the coil arrangement for determining a water content present within the tube, wherein the coil arrangement includes a resonance coil having a length-to-diameter ratio which is at least 3:1, and wherein the resonance coil include at least 10 turns.

According to a third aspect of the invention, there is provided a software product recorded on a machine readable medium, wherein the software product is executable upon computing hardware for implementing a method pursuant to the second aspect of the invention.

### DESCRIPTION OF THE DIAGRAMS

Embodiments of the present invention will now be described, by way of example only, with reference to the following diagrams wherein:

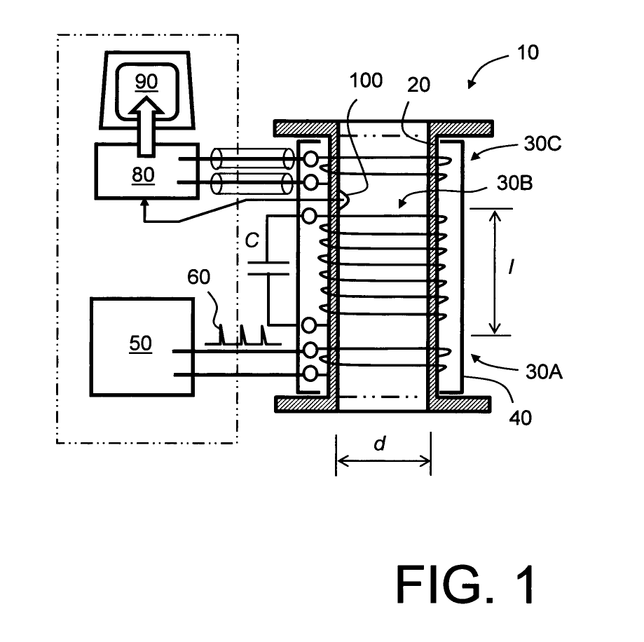

FIG. 1 is an illustration of an embodiment of a water content measuring apparatus pursuant to the present invention;

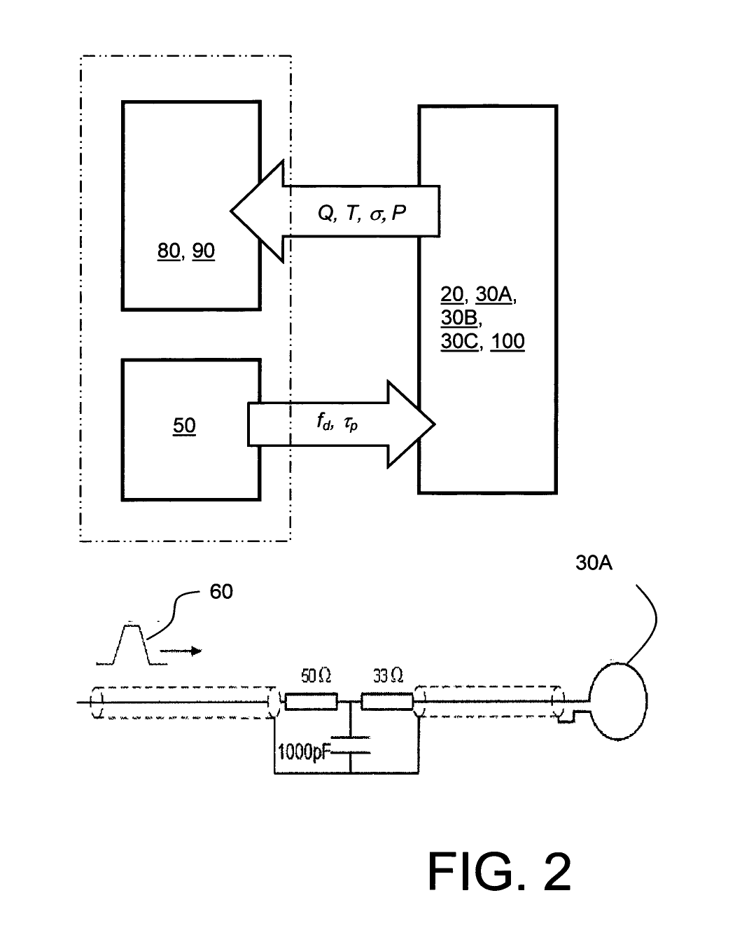

FIG. 2 is an illustration of signals to be analyzed in the apparatus of FIG. 1;

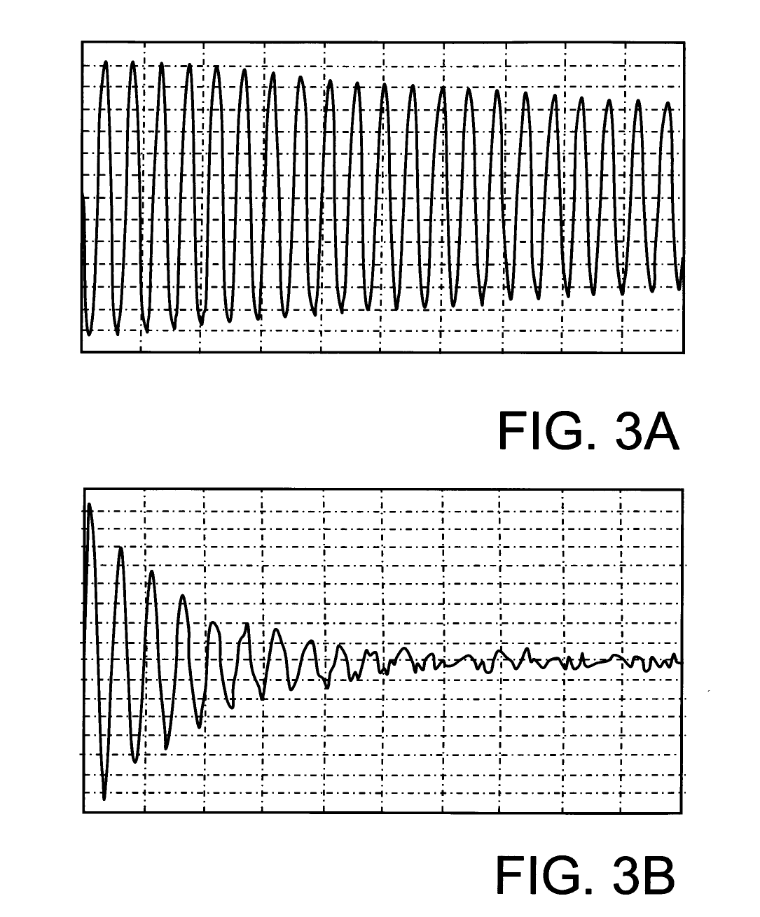

FIG. 3A is an illustration of a signal received from a pickup coil of the apparatus of FIG. 1 when a fluid flow tube of the apparatus is devoid of water;

FIG. 3B is an illustration of a signal received from the pickup coil of the apparatus of FIG. 1 when the fluid flow tube of the apparatus contains spring water;

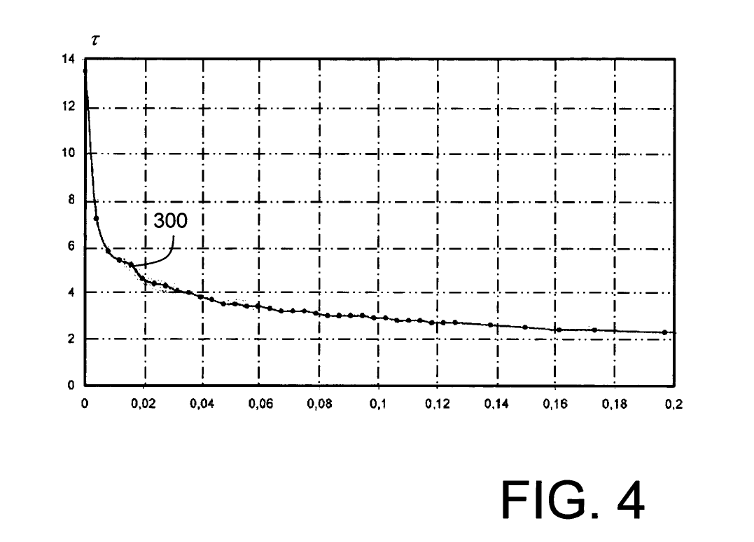

FIG. 4 is an illustration of changes in a parameter (tau, τ) representative of Q-factor as a function of a water content of the fluid flow tube of the apparatus of FIG. 1;

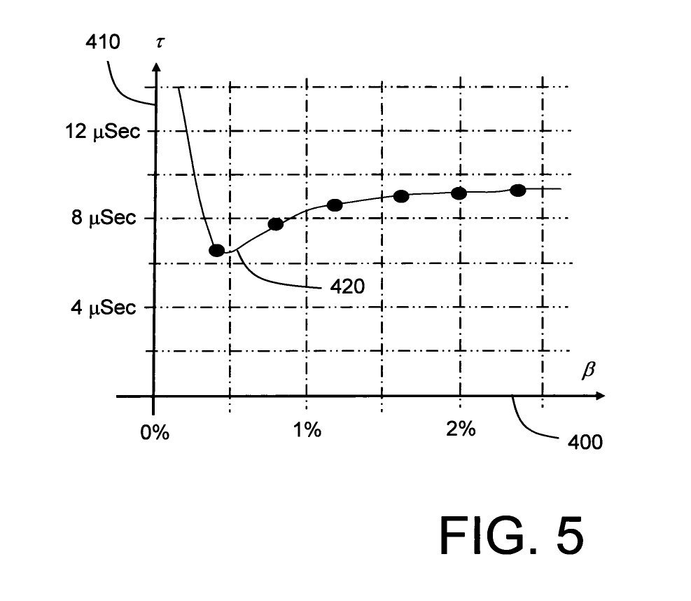

FIG. 5 is a graph illustrating sensitivity of the apparatus of FIG. 1 to saline solution;

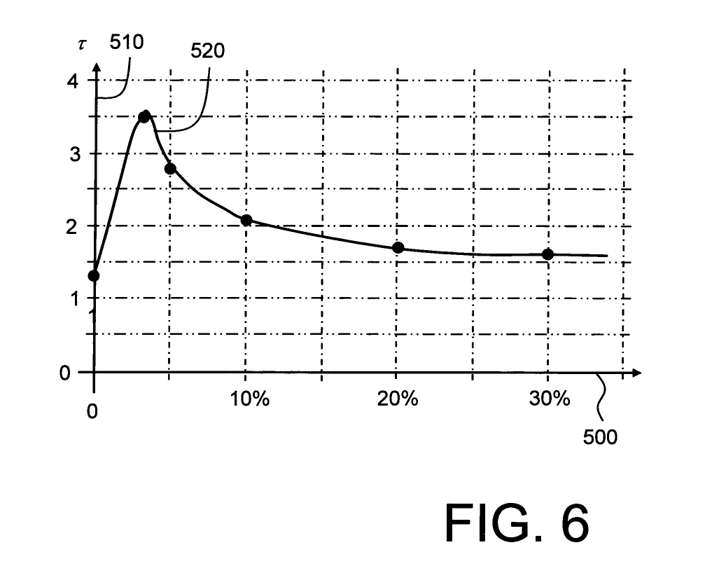

FIG. 6 is a graph illustrating sensitivity of the apparatus of FIG. 1 to salt weight in saline solution present within a sensing tube of the apparatus;

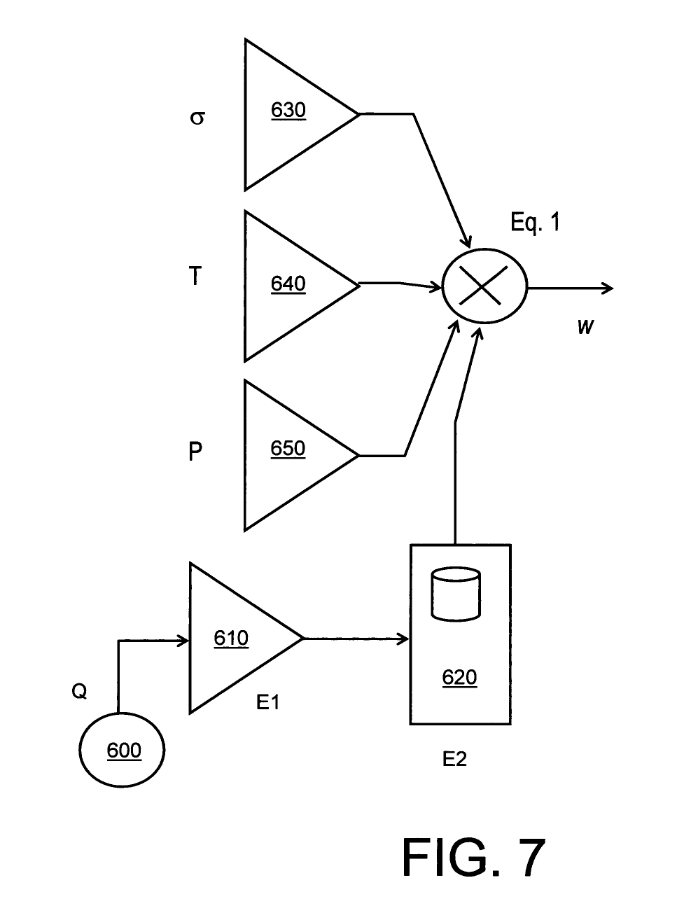

FIG. 7 is a schematic illustration of noise sources of a water content measuring apparatus pursuant to the present invention;

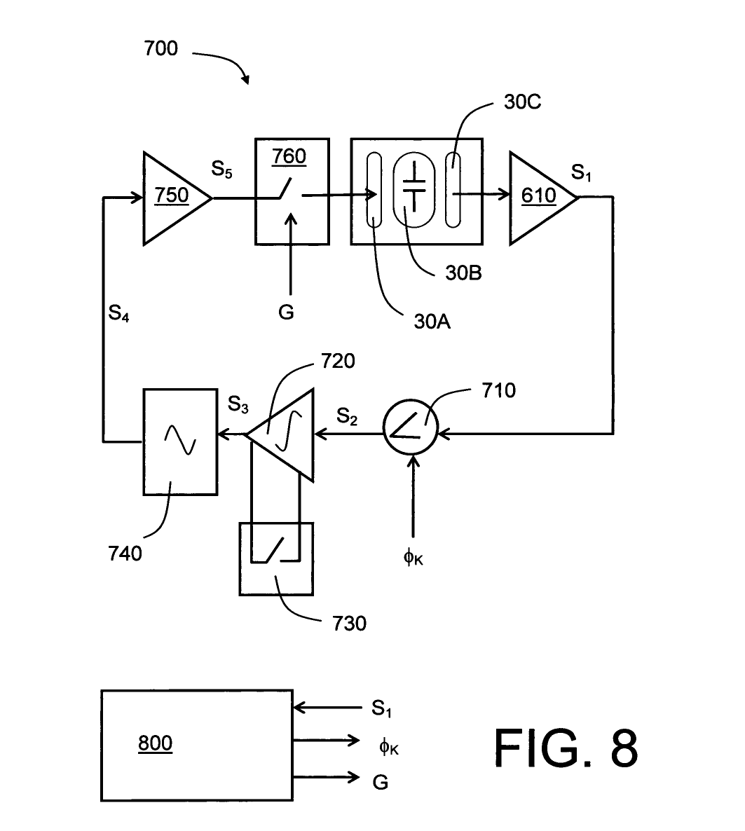

FIG. 8 is a schematic illustration of an electronic circuit for use when implementing a water content measuring apparatus pursuant to the present invention;

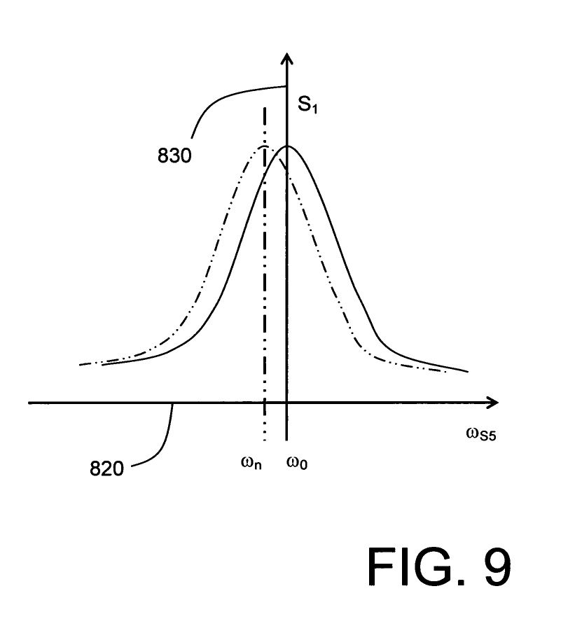

FIG. 9 is an illustration of a resonance characteristic of a sensing resonant coil arrangement of the apparatus associated with FIG. 7 and FIG. 8, illustrating a driven resonance ωₒ and an undriven natural resonance ωₙ;

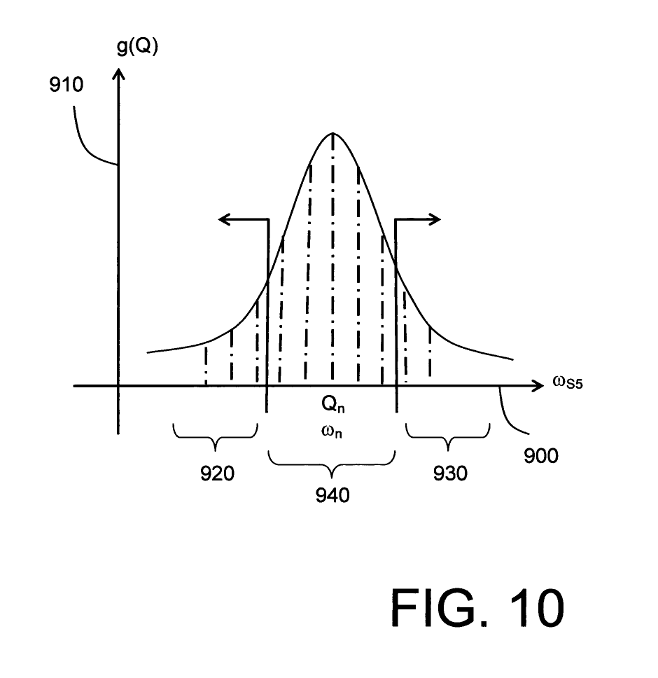

FIG. 10 is an illustration of a sample of measured Q-factors of a sensing coil arrangement of the apparatus associated with FIG. 7 and FIG. 8; and

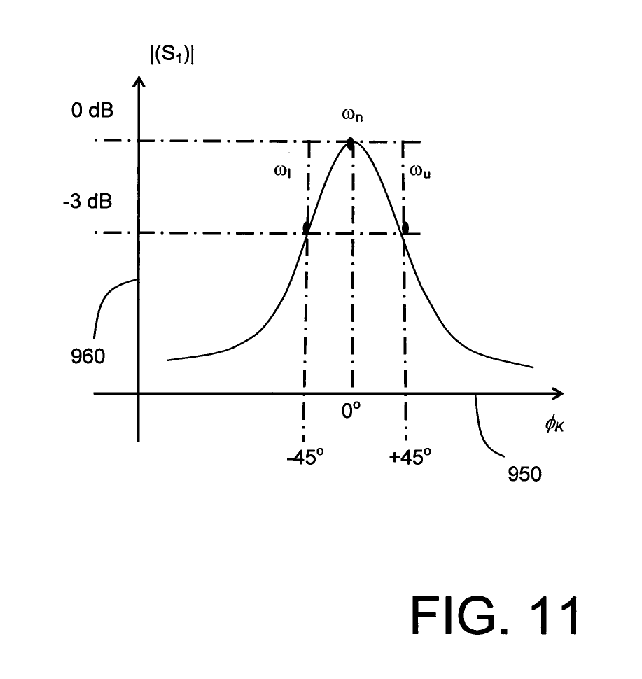

FIG. 11 is an illustration of a resonance characteristic of a sensing coil arrangement of the apparatus associated with FIG. 7 and FIG. 8.

In the accompanying diagrams, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### Description of Embodiments of the Invention

It is well known that cylindrical conductor coils exhibit electrical resonances on account of inductance and distributed capacitances associated with such conductor coils; such “distributed capacitances” contributed to resonant circuit tuning capacitors pursuant to the present invention. The distributed capacitances correspond to inter-winding capacitances. Moreover, the inductance arises on account of magnetic flux developed by the coils. However, as aforementioned, it is conventionally perceived that such coils are only capable of providing multiphase mixture measurement to an error deviation of a few percent. For measuring conditions of potential hydrate formation, it is necessary to measure water content to concentrations of a few parts per million (p.p.m.). Thus, it has been conventional practice to regard an electrical resonance coil as being quite unsuitable for use in making precision hydrate-related measurements.

Experimental studies associated with devising the present invention have surprisingly shown that suitable excitation of a coil having a sufficient number of turns and an adequate length in relation to its diameter allows water content measurements to be performed to concentrations as low as a few parts per million (p.p.m.). Such high accuracy measurement is feasible utilizing a water content measurement apparatus as illustrated in FIG. 1; the water content measurement apparatus is indicated generally by 10. The apparatus 10 includes a polymer material tube 20, for example fabricated from polycarbonate, acrylic-type or PEEK plastics materials; such polymer materials are chosen to exhibit relatively low dielectric losses at a frequency of several MHz. The tube 20 beneficially has an inside diameter d in a range of 70 to 90 mm, and a length provided with windings in a range of 280 mm to 320 mm; however, the apparatus 10 is susceptible to being adapted at larger diameters above 90 mm. The tube 20 is provided at its first end with an excitation coil 30A comprising a single turn. In a middle portion of the tube 20, there is provided a resonance coil 30B comprising in a range of 30 to 50 turns which is optionally terminated with a capacitor C of value 32 pF; for example, 34 turns for the coil 30B is found to function well in practice. The capacitor C is beneficially a high-quality capacitor exhibiting low dielectric losses at operating frequencies of a few MHz, for example a high-quality ceramic capacitor, Mica dielectric capacitor or sealed air-cored capacitor. The resonance coil 30B coupled to its associated capacitor C is operable to exhibit a resonance frequency in an order of a few MHz, for example in a range of 1 MHz to 5 MHz, although other operating frequencies can be employed if required. The resonance coil 30B is beneficially uniformly wound along the length l, such that the coil 30B has a diameter:length ratio in a range of 1:3 to 1:5. Ratios in excess of 1:5 can optionally be employed. Beneficially, the coil 30B is wound from Litz wire (namely individually insulated wire strands) or from thin Copper tape with associated insulation to reduce conductor skin-depth effects in the coil 30B from adversely affecting its Q-factor to detriment of sensitivity of the apparatus 10 to minute quantities of water present in the tube 20. Optionally, an outer conducting surface of windings of the coil 30B is silver plated to increase a resonance Q-factor of the coil 30B. Moreover, the tube 20 also includes a pickup coil 30C comprising a single turn. The capacitor C is beneficially spatially located in close proximity to the coil 30B as illustrated for obtaining most accurate measurement of water content, for example in gases flowing in operation through the tube 20 in conditions in which hydrate deposition would be expected to arise. The tube 20 and its coils 30A, 30B, 30C are furnished with an outer peripheral screening shield 40 fabricated from Aluminium sheet, stainless steel or similar. Beneficially, the shield is designed to be able to withstand a pressure that is likely to be encountered within the tube 20. Optionally, the Aluminium sheet employed to fabricate the shield 40 has a thickness which is less than 1 mm, for preferably less than 0.5 mm. Alternatively, or additionally, outer fibre glass or carbon composite shielding for the tube 20 and its coils 30A, 30B, 30C is employed.

The excitation coil 30A is coupled to a generator 50 which is operable, for example, to output a temporal series of pulses 60 having a pulse duration τₚ and a pulse repetition frequency fₚ. Beneficially, the pulse duration τₚ is much shorter than a period between pulses 60, namely

$$\frac{1}{{f}_{p}}$$

by at least an order of magnitude.

The pickup coil 30C is connected via two well-screened coaxial cables 70 to a signal processing unit 80 employing computing hardware executing software products for analyzing signals induced in operation in the pickup coil 30C to generate corresponding analysis results. The processing unit 80 is operable to present the analysis results on a display 90 indicative of concentration of water content present within the tube 20, for example potentially to trace levels as low as a few parts per million (p.p.m.) of water content being present within the tube 20. Optionally, the processing unit 80 is adapted to monitor water concentration, temperature and conductivity on an inside surface of the tube 20 for identifying conditions in which hydrate deposition is likely to arise.

Resonance characteristics of the coil 30B are strongly affected depending upon whether or not water present within the tube 20 is saline in nature. Salt content in a salt solution affects a freezing temperature of the solution, and therefore affects a temperature at which hydrate deposition can arise when the solution is present together with a hydrocarbon, for example methane or propane. On account of the highly conductive nature of saline solution, it is necessary for the apparatus 10 to include additionally a sensor arrangement 100 on an inside surface of the tube 20, wherein the sensor arrangement 100 includes a temperature sensor for measuring a temperature T of the inside surface of the tube 20 and a surface electrical conductivity sensor for measuring an electrical conductivity a of a film formed in operation of the inside surface of the tube 20. Signals associated with the sensor arrangement 100 conveyed to the processing unit 80 are illustrated in FIG. 2. The processing unit 80 is programmed to perform a computation represented by Equation 1 (Eq. 1):

w=F(Q,fᵣ,T,σ,P) Eq. 1

wherein
w=water concentration;
P=pressure within the tube 20;
Q=Q-factor of resonance of the coil 30B subject to excitation;
T=temperature of inside surface of the tube 20;
σ=electrical low-frequency or d.c. conductivity of a moisture film formed on the inside surface of the tube 20; and
F=a conversion function determined from experimental calibration measurements.

The function F is beneficially implemented as a lookup table implemented in computer memory of the processing unit 80. Optionally, the function F is determined empirically by performing a series of experimental tests to derive measurement data, and then synthesizing intermediate measurements by mathematical extrapolation to provide the function F as a continuously variable function. Alternatively, the function F can be derived analytically from theoretical consideration of the sensor arrangement 100. The Q-factor Q is determined from an envelope of a temporal signal decay characteristic as illustrated in FIG. 3A and FIG. 3B wherein the signal is described substantially by Equation 2 (Eq. 2):

$$s = {v}_{0} {e}^{\frac{t}{τ}} sin ω t \qquad Eq . 2$$

wherein
s=signal induced in the pickup coil 30C;
v₀=amplitude coefficient of the signal s;
τ=exponential decay time constant of the response signal arising from electrical responance of the coil 30B;
ω=resonance frequency of the coil 30B; and
t=time.

The sensor arrangement 100 can be implemented in various different ways. For example electrodes of the sensor arrangement 100 for measuring electrical conductivity can be implemented as annular ring electrodes around an inner circumferential surface of the tube 20 and disposed in a direction along an elongate axis of the tube 20. Alternatively, or additionally, electrodes of the sensor arrangement 100 for measuring electrical conductivity can be implemented as sectors of limited angular extent for sensing inhomogeneous deposition of hydrates onto the inner surface of the tube 20. Beneficially, the conductivity sensing electrodes are selected or treated to have a similar wetting characteristic to other parts of the tube 20 so that hydrate formation measurements provided by the apparatus 10 are as representative as possible for other tube connected to the tube 20. Similarly, the temperature sensor of the sensor arrangement 100 can be implemented as one or more individual temperature sensors which are spatially disposed for sensing temperature gradients within the tube 20. For purposes of computing Equation 1 (Eq. 1), an aggregate or average of the several temperature measurements from a plurality of temperature sensors of the sensing arrangement 100 can be used. The inside surface of the tube 20 is beneficially smooth for avoiding non-representative deposition of hydrate deposits onto the inside surface.

FIG. 3A and FIG. 3B are illustrations of resonance characteristics exhibited by the coil 30B as sensed using the pickup coil 30C. In a preferred embodiment of the invention, the coil 30B beneficially has 34 turns and is optionally tuned with a capacitor C having a capacitance value 32 pF. Alternatively, the coil 30B has 15 turns and is optionally tuned with a capacitor C having a capacitance value 100 pF. Correct impedance matching of the excitation coil 30A is highly beneficial for obtaining an uncluttered waveform as presented in FIG. 3A and FIG. 3B; the impedance matching corresponds to a filter which reduces excitation of higher-order resonances within the coil 30B, for example at frequencies approximately an order of magnitude above its main resonance frequency, for example at around 35 MHz when the coil 30B has a fundamental resonance around 3.5 MHz. Matching components as illustrated in FIG. 2 including a T-arrangement comprising a series connection of 50Ω, 33Ω resistors and a 1000 pF capacitor to signal ground at a midpoint between the resistors has been found from experimental studies to function well for the apparatus 10. A relatively high Q-factor resonance of FIG. 3A corresponds to the tube 20 devoid of water; in contrast, FIG. 3B corresponds to a lower Q-factor response arising when the tube 20 contains a quantity of fresh water. By accurate measurement of Q-factor executed by the processing unit 80 when processing the pickup signal from the pickup coil 30C, the apparatus 10 is capable of detecting very small concentrations of water within the tube 20, for example to concentrations of a few parts per million (p.p.m.). The very high sensitivity of the apparatus 10 is also illustrated in FIG. 4 which is a graph having an abscissa axis representative of water fraction β present within the tube 20, and an ordinate axis providing a measured parameter (tau, τ) indicative of the Q-factor of resonance of the coil 30B a sensed via the pickup coil 30C.

As will be elucidated in greater detail later, by exciting the coil 30B to resonate, there is providing thereby an indication, via Q-factor measurement pursuant to the present invention, for establishing whether or not hydrate formation is likely to occur within a region encircled by the coil 30B. The Q-factor measurement is beneficially determined from a natural undriven Q-factor of the coil 30B, namely without disturbances arising from a finite driving impedance of the excitation coil 30A. The pickup coil 30C is beneficially arranged to represent a high impedance to the coil 30B, and thereby has a negligible influence upon the resonance of the coil 30B. Beneficially, the excitation coil 30A is driven momentarily to excite the coil 30B into resonance, and then the resonance of the coil 30B is allowed to decay naturally with the excitation coil 30A “open circuit” so that the excitation coil 30A does not influence the Q-factor of the coil 30B, namely permits the coil 30B to exhibit its natural resonance having a natural resonant frequency ωₙ. By monitoring the natural resonance of the coil 30B, an improved measurement accuracy can be achieved from the apparatus 10. In the apparatus 10, the Q-factor measurement of the coil 30B can either be performed in a continuous driven manner or in a pulse-resonant excited manner, or by employing a mixture of such measurement techniques.

The apparatus 10 provides a benefit that its pulse excitation manner of operation enables the generator 50 and the data processor 80 to be located spatially remotely from the tube 20 and its associated coils 30A, 30B, 30C and optional sensor arrangement 100. Such flexibility is highly beneficial when the tube 20 is required to operate at temperatures which would be hostile to electronic components associated with the data processor 80 and the generator 50. The apparatus 10 is susceptible to being employed in a large range of applications. For example, the apparatus 10 can be used in ocean-bed hydrate handling equipment, in separation tanks, down boreholes, in carbon dioxide capture and sequestration systems associated with climate change carbon tax funded facilities, in chemical industries, in space probes and similar. Measurement methods employed in the apparatus 10 will be described in more detail later.

It will be appreciated that the apparatus 10 is not operable to measuring a presence of hydrate deposits directly, but rather is able to provide an indication of a likelihood of hydrate deposit formation (hydrate ice crystals) based upon measured conditions of conductivity, temperature and pressure in combination with determining a concentration of water present within the tube 20. Optionally, the generator 50 is operable to excite the coil 30A by way of a repetitive burst of a plurality of pulses as an alternative to periodic single pulses; such burst excitation enables a better signal-to-noise (S/N) to be achieved in relation to electronically-generated noise arising within the apparatus 10, in combination with a reduced tendency to excite higher order resonances within the coil 30B.

In FIG. 1, the peripheral screening shield 40 is described in the foregoing as being fabricated from Aluminium. Alternatively, the screen 40 is fabricated from a recognized type of steel which is able to withstand gas and liquids which the apparatus 10 will encounter during transportation and operation. A region between an outside surface of the tube 20 and the screen 40 is beneficially filled with a mechanical robust insulating material exhibiting a relative permeability of approximately unity; for example the coils 30A, 30B, 30C can beneficially be appropriately encapsulated (namely “potted”) in a hydrocarbon polymer materials resin, for example an epoxy or polyurethane material. Optionally, the screen 40 includes fibre glass, carbon fibre or other strong polymer structural components, for example fabricated from stainless steel which can withstand a pressure within the tube 20 and thereby enable the instrument 10 to survive structurally in an unlikely event that the tube 20 ruptures in operation.

Referring again to Equation 1 (Eq. 1), the apparatus 10 operates to measure subtle characteristics whose nature is not generally appreciated. For example, a kink 500 in the curve of FIG. 4 is not a measurement inaccuracy, but rather a genuine relaxation effect resulting from spontaneous momentary alignments of groups of polarized water molecules to form larger momentary dipole moments which are many orders of magnitude larger than the dipole moments of individual water molecules. Such larger dipole moments are observed in the formation of ice crystals. In FIG. 5, there is a shown a graph pertaining to the Q-factor exhibited by the coil 30B as a proportion of saline solution within the tube 20 is varied. An abscissa axis 400 denotes a percentage of saline solution present in the tube 20 and an ordinate axis 410 denoting the time constant tau, τ of resonance of the coil 30B; the Q-factor Q of the coil 30B is directly susceptible to being computed from the time constant tau, τ. It will be observed in FIG. 5 that a minimum Q-factor occurs at a saline proportion β of around 0.5% with a high sensitivity below 0.5%, namely below 5000 p.p.m., wherein discrimination of presence of saline solution to within tens' of p.p.m. is achievable using the apparatus 10.

In FIG. 6, a response of the apparatus 10 to saline solution within the tube 20 is shown, wherein an abscissa axis 500 denotes percentage weight of salt within a saline solution present within the tube 20, and an ordinate axis 510 denotes the time constant tau, τ. The resonance characteristic of the coil 30B exhibits a distinct peak 520 at around 3% salt (Sodium Chloride, NaCl) by weight present in the solution corresponding to greatest Q-factor, reducing with salt percentage above 3% as conductivity of the solution increases and also falling for concentrations below 3% on account of aforementioned relaxation effects caused by spontaneous momentary polarisation alignment of water molecules to create a large effective dipole moment. Between 0% salt weight content and 3% salt weight content, increasing salt content hinders spontaneous association of water molecules to form a large momentary effective dipole moment by way of Chlorine atoms screening highly polarized hydrogen atoms (protons), thereby resulting in a corresponding progressive increase in Q-factor. Both FIG. 5 and FIG. 6 exhibit a rapidly changing measurement characteristic near zero which imparts the apparatus 10 with excellent measurement characteristics for trace amounts of fresh water or saline solution. Such a measurement characteristic is well suited for identifying conditions where there is a potential risk of hydrate deposits being formed which can block tubes, for example in an offshore gas production and processing facility.

In FIG. 7, sources of noise arising within the apparatus 10 are illustrated schematically. These noise sources influence an accuracy to which the Q-factor of the coil 30B can be measured. The Q-factor of the coil 30B is greatest when its encircled region is filled with dry gas; this is conveniently referred to as being Q_{dry}. When traces of fresh water or saline water are introduced into the encircled region, the Q-factor of the coil 30B is reduced; this is conveniently referred to as being Q_{wet}. The Q-factor Q_{dry} is influenced by the temperature T, for example as a result of winding resistances of the coil 30B changing with the temperature T. Thus, inherent in Equation 1 (Eq. 1) is a subtraction function as described in Equation 3 (Eq. 3):

w=F((Q_{dry}(T)−Qₛₑₜ(T)),fᵣ,T,σ,P) Eq. 3

Q_{dry}(T) can be determined by accurate measurement. Q_{wet}(T) is determined as the apparatus 10 is employed in practice. It will be appreciated that Q_{dry} and Q_{wet} can be relatively large numbers, for example in an order of 100 or more, and hence need to be measured to high precision for detecting occurrence of water to a sensitivity in an order of p.p.m. Such precision is influenced by noise and drift effects occurring within the apparatus 10 when in use.

In FIG. 7, the sources of noise occurring within the apparatus 10 include a first noise source 600 affecting the Q-factor arising from flow turbulence within a spatial region surrounded by the tube 20 surrounded by the coil 30B. Such flow turbulence is quasi-constant within a time period of signal decay illustrated in FIG. 3A and FIG. 3B, but will vary from one measurement of Q-factor of the coil 30B to another thereof over a monitoring period of several seconds or minutes, for example. Electronic noise E1 arising in an electronic amplifier 610 receiving signals from the pickup coil 30C arises, but is relatively constant; however, the electronic noise E1 is influenced by an operating temperature of the amplifier 610. Beneficially, the amplifier 610 is cooled by Peltier elements or a cryogenic engine to reduce its electronic noise E1. Digital electronic circuits 620 which receive an output signal from the amplifier 610 cause electronic noise E2, for example quantization noise, which is beneficially reduced by suitable design choice of components, for example by employing high-resolution ADC components for converting amplified analog signals from the amplifier 610 into corresponding digital sampling data. Noise sources 630, 640, 650 are associated with conductivity measurements, temperature measurements and pressure measurements respectively and can arise from corrosion (i.e. drift effects), electrochemical effects and ageing of electronic components. In practice, the noise source 600 is dominant and beneficially requires novel approaches to measurement technique pursuant to the present invention to obtain p.p.m. measurement accuracy results when detecting a presence of water within the tube 20.

Measurements of resonance Q-factor of the coil 30B are beneficially performed using a circuit as illustrated in FIG. 8. The circuit is indicated generally by 700 and includes a gated phase-locked-loop (PLL) including the aforesaid amplifier 610 for receiving a signal from the pickup coil 30C, a phase detector 710 for receiving an output signal S₁ of the amplifier 610, a phase integrator 720 for receiving a phase error output signal S₂ of the phase detector 710 wherein the phase integrator 720 is provided with an associated gating switch 730 for locking an output signal S₃ of the integrator 720 when required, a voltage-controlled oscillator (VCO) 740 controlled by the output signal S₃ of the phase integrator 720, a drive amplifier 750 for receiving an output signal S₄ from the oscillator (VCO), and a switch 760 for receiving an output signal S₅ of the drive amplifier 750 and coupled to the excitation coil 30A. There is also included a microprocessor 800 for providing a phase reference signal φ_{K} to the phase detector 710, for providing a gating signals G to the switches 730, 760, and for receiving the signal S₁. The microprocessor 800 is operable to execute software products recorded on machine-readable data storage media to generate an output indicative of water content as measured by the apparatus 10.

The phase integrator 720 is implemented either by analog components or digitally, and is provided with the switch 730 for momentarily holding the output signal S₃ of the integrator 720 constant, thereby maintaining an output frequency of the signal S₄ momentarily constant. Optionally, the oscillator 740 synthesizes a sine-wave for the signal S₄ and its output is derived from a stable high-frequency reference, for example derived from a high-stability quartz-crystal oscillator forming a part of the oscillator 720.

In operation, the circuit 700 functions in two modes, namely a first excitation mode and a second measurement mode. In the first excitation mode, the oscillator 730 is swept to find a driven resonance frequency ω₀ of the coil 30B and the phase signal φ_{K} is then adjusted by the microprocessor 800 so that the amplitude of the signal S₁ is adjusted to its maximum amplitude; this occurs with the switch 760 closed to couple the signal S₅ to the excitation coil 30A. When a maximum amplitude for the signal S₁ is achieved, the coil 30B is resonating at its driven resonance frequency ω₀.

Thereafter, the circuit 700 is operated in its second mode, wherein the oscillator 730 is locked at the frequency ω₀ via use of the switch 730 controlled from the microprocessor 800; optionally, the oscillator 740 is adjusted slightly down in frequency to an estimate of its natural undriven resonant frequency ωₙ, namely when the coils 30A, 30C are effectively open-circuit. The microprocessor 800, via the switch 760, then pulse excites the excitation coil 30A, and hence excites the coil 30B, using one or more pulses preferably at a frequency ωₙ and thereafter opens the switch 760, so that the coil 30B exhibits a natural resonance at a frequency ωₙ with a decay envelope akin to that illustrated in FIG. 3A and FIG. 3B from which a measure of Q-factor may be derived using the microprocessor 800 to digitize and analyze the signal S₁ during the decay envelope, for example as illustrated in FIG. 3A and FIG. 3B. The first mode followed by the second mode is beneficially implemented within a time period during which the noise source 600 on FIG. 7 is quasi-constant.

FIG. 9 illustrates a difference between the driven resonance frequency ω₀ of the coil 30B in comparison to the natural resonance frequency ωₙ. An amplitude of the signal S₁ is denoted along an ordinate axis 830 and the driving frequency of the signal S₅ is denoted along an abscissa axis 820.

By repeating the first mode followed promptly by the second mode a plurality of times, a series of Q-factor measurements Q₁, . . . Qₘ are obtained during a measurement time period. On account of turbulence noise arising within the tube 20 and electronic noise as aforementioned, the series of Q-factors fall generally within a Gaussian-bell frequency-of-occurrence distribution as illustrated in FIG. 10 as computed by the microprocessor 800. An abscissa axis 900 denotes frequency of resonance as approximately determined from the signal S₅, and an ordinate axis 910 denotes a frequency-of-occurrence of given Q-factors in the sample of Q-factor Q₁, . . . Qₘ, denoted by g(Q). In the results illustrated, the microprocessor 800 determines a most representative Q-factor to employ for Equation 1 (Eq. 1) by performing analytical processing on the series of measured Q-factors Q₁, . . . Qₘ as will now be described.

In signal processing performed by the microprocessor 800, lower and upper results denoted by 920, 930 are beneficially ignore, namely truncated, and more central Q-factor results are in a region 940 are employed to derive a reliable measure of the Q-factor to employ for Equation 1 (Eq. 1). For example, the upper and lower results 920, 930 correspond to upper and lower quartiles of the Q-factor distribution of FIG. 10. In a first processing method, the results in the region 940 are averaged to derive a representative value of Q-factor at the natural resonant frequency ωₙ of the coil 30B. In an alternative second processing method, the Q-factor results in the region 940 are subject to one or more auto-correlations which defines very accurately a best measurement of Q-factor at an auto-correlation peak. By such an approach, the microprocessor 800 of the instrument 10 is capable of determining a representative value for the Q-factor of the coil 30B to extreme precision, which subsequently enables water factions present in the tube 20 in vicinity of the coil 30B to be measure to potentially p.p.m. accuracy using Equation 1 (Eq. 1).

In overview, the circuit 700 is beneficially operable to measure the Q-factor of the coil 30B at natural resonance ωₙ, and then process corresponding Q-factor measurements to remove stochastic errors which, in turn, enables Equation 1 (Eq. 1) to be employed to high accuracy to determine a water faction present within the tube 20, for example potentially to p.p.m. accuracy.

As an alternative, the circuit 700 is capable of being employed in other manners for measuring Q-factor of the coil 30B. For example, the circuit 700 is adjusted to find a driven peak resonance of the coil 30B at a frequency ω₀, and then a phase adjustment provided by way of the phase control φ_{K} is applied by the microprocessor 800 to switch between phase intervals below and/or above resonance of the coil 30B, for example corresponding to −3 dB points, and corresponding Q-factor measurements Q₁, . . . Qₘ obtained which are then optionally processed as aforementioned to correct for stochastic influences to derive a final measure of the Q-factor to employ in Equation 1 (Eq. 1) for computing the water faction w present in the tube 20. Such continuous non-pulse measurement is illustrated in FIG. 11 where an abscissa axis 950 denotes phase and an ordinate axis 960 denotes amplitude of the signal S₁, for example for −3 dB, 0 dB, −3 dB points corresponding to operating control phases of −45°, 0°, +45° respectively, corresponding to excitation frequencies ωₗ, ω₀, ωᵤ respectively; a measure of Q-factor of the coil 30B can be computed readily from the frequencies ωₗ, ω₀, ωᵤ.

From the foregoing, it will be appreciated that operation of the instrument 10 to measure water content to an accuracy of p.p.m. requires that the coil 30B be appropriately designed together with advanced signal processing techniques being employed to reduce error sources so that a highly reliable and accurate measurement of Q-factor can be derived from which the water fraction w present can be accurately and reliably computed.

Modifications to embodiments of the invention described in the foregoing are possible without departing from the scope of the invention as defined by the accompanying claims. Expressions such as “including”, “comprising”, “incorporating”, “consisting of”, “have”, “is” used to describe and claim the present invention are intended to be construed in a non-exclusive manner, namely allowing for items, components or elements not explicitly described also to be present. Reference to the singular is also to be construed to relate to the plural. Numerals included within parentheses in the accompanying claims are intended to assist understanding of the claims and should not be construed in any way to limit subject matter claimed by these claims.

1. A water content measuring apparatus for measuring water content present in a fluid flow through a tube, the apparatus comprising a generator for generating in operation an excitation signal, a coil arrangement disposed around the tube adapted to be excited into resonance by the excitation signal and interact with the fluid flow through the tube, and a signal processor adapted to receive resonance signals from the coil arrangement for determining a water content present within the tube, wherein the coil arrangement includes a resonance coil.

2. A water content measuring apparatus as claimed in claim 1, wherein said generator is arranged to generate the excitation signal to be a temporal series of excitation pulses.

3. A water content measuring apparatus as claimed in claim 1, wherein the tube and its associated coil arrangement are surrounded by an electrostatic shield for screening the coil arrangement when in operation.

4. A water content measuring apparatus as claimed in claim 1, further including a sensor arrangement for sensing low-frequency electrical conductivity and temperature on an inside wall of the tube and for providing corresponding sensor signals to the data processor for enabling the signal processor to compute the water content within the tube independently of the salinity of the water content.

5. A water content measuring apparatus as claimed in claim 1, wherein the coil arrangement includes excitation, resonance and pickup coils, wherein the excitation coil is coupled to the generator, the pickup coil is coupled to the signal processor, and the resonance coil is coupled to a tuning capacitor for providing a resonance characteristic which is sensitive to water content within the tube.

6. A water content measuring apparatus as clamed in claim 5, wherein the coils include at least one of: individually insulated Litz wires, and insulated metallic tape.

7. A water content measuring apparatus as claimed in claim 1, wherein at least one of the generator and the signal processor are adapted to be spatially remote from the tube and its coil arrangement in operation.

8. A water content measuring apparatus as claimed in claim 1, wherein the apparatus is adapted to monitor conditions for potential hydrate formation within the tube, and wherein detection of minute quantities of water present within the tube is indicative of potential early hydrate formation.

9. A water content measuring apparatus as claimed in claim 1, wherein the tube comprises at least one of: polycarbonate polymer, acrylic polymer, and PEEK.

10. A method of measuring water content present in a fluid flow through a tube, the method comprising:
(a) using a generator to generate in operation an excitation signal for exciting a coil arrangement disposed around the tube for interacting with the fluid flow through the tube; and
(b) receiving at a signal processor resonance signals from the coil arrangement for determining a water content present within the tube, wherein the coil arrangement includes a resonance coil.

11. A software product recorded on a machine readable medium, wherein the software product is executable upon computing hardware for implementing a method as claimed in claim 10.

12. A water measuring apparatus as claimed in claim 1, wherein the resonance coil has a length-to-diameter ratio of at least 3:1.

13. A water measuring apparatus as claimed in claim 1, wherein the resonance coil includes at least 10 turns.

14. A water measuring apparatus as claimed in claim 1, wherein the generator generates pulses having a pulse duration substantially shorter than a period between pulses.

15. A method as claimed in claim 10, wherein the resonance coil has a length-to-diameter ratio of at least 3:1.

16. A method as claimed in claim 10, wherein the resonance coil includes at least 10 turns.

17. A method as claimed in claim 10, wherein the generator generates pulses have a pulse duration substantially shorter than a period between pulses.
